(19) United States
(12) Patent Application Publication
(10) Pub. No.: US 2013/0224964 A1
(43) Pub. Date: Aug. 29, 2013

(54) Method for Forming Dielectric Film Containing Si-C bonds by Atomic Layer Deposition Using Precursor Containing Si-C-Si bond

(71) Applicants: Atsuki Fukazawa, Tokyo (JP); Noboru Takamure, Kawasaki-shi (JP)

(72) Inventors: Atsuki Fukazawa, Tokyo (JP); Noboru Takamure, Kawasaki-shi (JP)

(73) Assignee: ASM IP HOLDING B.V., Almere (NL)

(21) Appl. No.: 13/406,791

(22) Filed: Feb. 28, 2012

(51) Int. Cl. H01L 21/31

(52) U.S. Cl. 438/765; 257/E21.24

(57) ABSTRACT

A method of forming a dielectric film having Si—C bonds on a semiconductor substrate by atomic layer deposition (ALD), includes: (i) adsorbing a precursor on a surface of a substrate; (ii) reacting the adsorbed precursor and a reactant gas on the surface; and (iii) repeating steps (i) and (ii) to form a dielectric film having at least Si—C bonds on the substrate. The precursor has a Si—C—Si bond in its molecule, and the reactant gas is oxygen-free and halogen-free and is constituted by at least a rare gas.

### BACKGROUND OF THE INVENTION

1. Field of the Invention

The present invention relates generally to semiconductor integrated circuit manufacturing and, more particularly to a method of forming a dielectric film having at least Si—C bonds on a semiconductor substrate by atomic layer deposition (ALD).

2. Description of the Related Art

SiC, SiCN, SiN and other silicon-containing insulation films were adopted as etching stopper films and Cu diffusion blocking films for devices installed with Cu wiring. For installing devices with Cu wiring, damascene structures are widely used, and as a result, these films are effectively adapted as etching stopper films and Cu diffusion blocking films by modifying their characteristics depending on required specifications. When applying these films to damascene structures, since films are formed mostly on planar surfaces, those skilled in the art have been forming these films using plasma CVD, where the films tend to possess low dielectric constant, low leakage current, dry-etch selectivity against SiOC films, and good Cu diffusion blocking property.

As device nodes are advanced, in order to avoid RC delays, the films are used in combination with airgaps. For forming airgaps, since films are formed on wiring provided in conformational structures, barrier films having not only metal diffusion blocking property but also good step covering property (coverage) are required. Further, for forming semiconductor circuit patterning, absorption films having etch stopper functions and reflection blocking functions are required, and also, the films are required to possess step covering property since deposition on conformational structures is conducted.

As dielectric films having good step coverage and barrier property, silicon carbide films such as SiCN and SiC films have been used by a conventional method using a combination of plasma CVD for formation and etching for patterning. However, as finer patterning is required, it becomes more difficult for the conventional method to provide not only good step covering property but also pattern density independency. In view of the above, development of silicon carbide films using atomic layer deposition (ALD) is underway. In order to promote chemisorption of a precursor on a surface, use of a precursor containing halogen has been studied. However, handling halogen-containing materials exerts additional burdens on operation systems, and controllable ranges using process parameters are narrow since the processes still require both film formation and etching to obtain desired dimensions of films conforming to the shapes and dimensions of an underlying layer on which the films are deposited.

Some embodiments of the present invention provide technology which resolves at least one of the problems involved in the conventional methods.

Any discussion of problems and solutions involved in the related art has been included in this disclosure solely for the purposes of providing a context for the present invention, and it should not be taken as an admission that any or all of the discussion were known at the time the invention was made.

### SUMMARY

An embodiment of the present invention provides a method of forming a dielectric film having Si—C bonds on a semiconductor substrate by atomic layer deposition (ALD), which comprises:

(i) adsorbing a precursor on a surface of a substrate, said precursor having a Si—C—Si bond in its molecule;

(ii) reacting the adsorbed precursor and a reactant gas on the surface, said reactant gas being oxygen-free and halogen-free and being constituted by at least a rare gas; and

(iii) repeating steps (i) and (ii) to form a dielectric film having at least Si—C bonds on the substrate.

A reactant gas constituted by predominantly a rare gas in an excited state can reach sidewall and bottom surfaces of fine patterns of a substrate and effectively reacts with a precursor having a Si—C—Si bond chemisorbed on the surfaces, thereby forming a film having an excellent step coverage in a manner less dependent on pattern density. Preferably, He is used as a reactant gas in an oxygen-free and halogen-free environment.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not necessarily to scale.

FIG. 1 is a schematic representation of a PE-ALD apparatus for depositing a dielectric film usable in some embodiments of the present invention.

FIG. 2 shows process steps of a PE-ALD method for depositing a dielectric film according to an embodiment of the present invention.

FIG. 3 shows process steps of a thermal ALD or radical-enhanced ALD method for depositing a dielectric film according to another embodiment of the present invention.

### DETAILED DESCRIPTION

In this disclosure, a “gas” may include vaporized solid and/or liquid and may be constituted by a single gas or a mixture of gases. Likewise, “a” refers to a species or a genus including multiple species. In this disclosure, “a film having at least Si—C bonds” may refer to a film characterized by Si—C bonds, a film constituted mainly or predominantly by Si—C bonds, a film categorized as Si—C films, and/or a film having a main skeleton substantially constituted by Si—C bonds. Also, “a precursor having a Si—C—Si bond in its molecule” may refer to a precursor having at least one Si—C—Si bond in a main skeleton of the molecule, a precursor being an adduct having a portion having at least one Si—C—Si bond, a precursor characterized by a Si—C—Si bond or Si—C—Si bonds, or a precursor constituted mainly or predominantly by a Si—C—Si bond or Si—C—Si bonds.

In this disclosure, the precursor may include a rare gas as a carrier gas when the precursor is vaporized and carried by a rare gas, and the flow of the precursor is controlled by the inflow pressure (the pressure of gas flowing into a reactor). Further, the precursor is a material from which the film is derived and which provides main elements of the film. The precursor contains silicon and can be mixed with a secondary precursor which does not contain silicon such as hydrocarbon gas for a film having Si—C bonds. The reactant gas may be any gas causing surface reaction in an excited state with the precursor chemiadsorbed on a surface to fix a monolayer of the precursor on the surface by ALD. In this disclosure, “oxygen-free and halogen-free environment” refers to an environment which is adjacent to the surface to be treated and which contains substantially or completely no oxygen or halogen or an immaterial amount of oxygen or halogen. The reactant gas can be continuously supplied separately from the precursor and/or as a carrier gas of the precursor to a reactor and excited at a specific timing by a plasma, or can be supplied separately from the precursor at a specific timing and thermally excited, or radicals of the reactant gas can be supplied from a remote plasma unit to the reactor at a specific timing. In some embodiments, the reactant gas also functions as a purge gas when the reactant gas is continuously introduced. In the above, “continuously” refers to without breaking a vacuum, without interruption as a timeline, without changing treatment conditions, immediately thereafter, as a next step, or without a discrete physical or chemical boundary between two structures in some embodiments. In some embodiments, “film” refers to a layer composed of multiple monolayers (composed of the same monolayers or different monolayers) and continuously extending in a direction perpendicular to a thickness direction substantially without pinholes to cover an entire target or concerned surface, or simply a layer covering a target or concerned surface. A film or layer may be constituted by a discrete single film or a layer having a common characteristic. In this disclosure, any defined meanings do not necessarily exclude ordinary and customary meanings in some embodiments.

In the present disclosure where conditions and/or structures are not specified, a skilled artisan in the art can readily provide such conditions and/or structures, in view of the present disclosure, as a matter of routine experimentation. Also, in the present disclosure including the examples described above, any ranges applied in some embodiments may include or exclude the lower and/or upper endpoints, and any values of variables indicated may refer to precise values or approximate values and include equivalents, and may refer to average, median, representative, majority, etc. in some embodiments.

As described above, in some embodiments, the method of forming a dielectric film having Si—C bonds on a semiconductor substrate by atomic layer deposition (ALD) comprises:

(i) adsorbing a precursor on a surface of a substrate, said precursor having a Si—C—Si bond in its molecule;

(ii) reacting the adsorbed precursor and a reactant gas on the surface, said reactant gas being oxygen-free and halogen-free and being constituted by at least a rare gas; and

(iii) repeating steps (i) and (ii) to form a dielectric film having at least Si—C bonds on the substrate.

In some embodiments, the reactant gas consists of the rare gas. In some embodiments, the reactant gas consists of the rare gas and at least another gas constituted by N, H, and/or C. In some embodiments, the other gas is selected from the group consisting of nitrogen, ammonia, hydrogen, hydrocarbon, and nitrogen-hydrocarbon. In some embodiments, the reactant gas is selected according to the type of the dielectric film and the deposition conditions and is at least one selected from the group consisting of N₂, NH₃, NₓH_{y}, NₓH_{y}C_{z}, CₐH_{b}, CₐF_{b}, CₐH_{b}N_{c}, and H₂ wherein x, y, z, a, b, and c are integers (e.g., x is one or two, and a is three to six). In some embodiments, the other gas is hydrogen and/or nitrogen. For SiCN films, a reactant gas containing nitrogen may be used. Hydrogen is effective to promote surface reaction so that the RF power and application duration can be lowered (e.g., an RF power of less than 200 W). In some embodiments, the rare gas is at least one rare gas selected from Ar, He, Kr, and Xe. In some embodiments, the rare gas is He. He may be highly effective to increase step coverage.

In some embodiments, the precursor is at least one compound selected from the group consisting of:

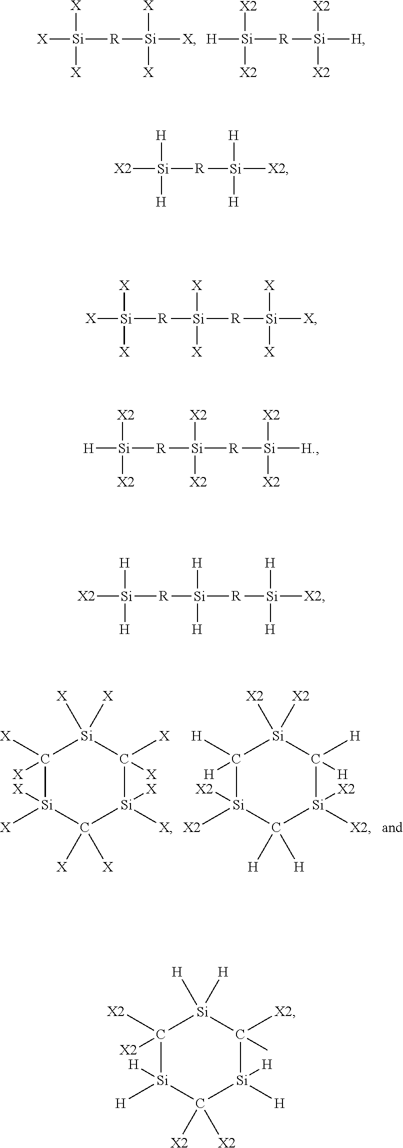

wherein X is H₂ or NₓH_{y}, X2 is CₓH_{y} or NCₓH_{y}, R is CₓH_{y}, NH₂, or NCₓH_{y}, where subscript x and y are integers.

In some embodiments, the ALD is plasma enhanced ALD. In some embodiments, steps (i) and (ii) comprise:

(a) supplying the precursor and the reactant gas to a reaction space where the substrate is placed, without applying RF power, thereby adsorbing the precursor on the surface of the substrate;

(b) continuously supplying the reactant gas while discontinuing the supply of the precursor, without applying RF power, thereby purging the surface of the substrate;

(c) applying RF power to the reaction space while continuously supplying the reactant gas without the supply of the precursor, thereby reacting the adsorbed precursor and the reactant gas on the surface; and

(d) continuously supplying the reactant gas while discontinuing the supply of the precursor, thereby purging the surface of the substrate,

where steps (a) to (d) constitute one cycle of the plasma enhanced ALD.

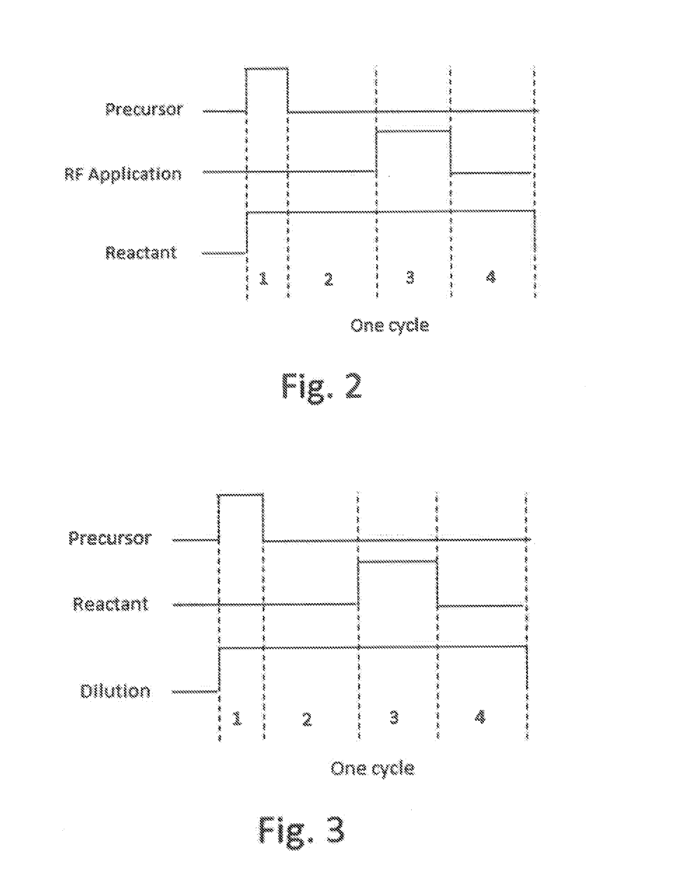

FIG. 2 shows process steps of a PE-ALD method for depositing a dielectric film according to an embodiment of the present invention. In FIG. 2, the PE-ALD method repeats a cycle which is constituted by steps 1 to 4. In step 1 which is a precursor adsorption step, a precursor is supplied in a pulse, a reactant gas is supplied, and no RF power is applied. In step 2 which is a purge step, no precursor is supplied, the reactant gas is continuously supplied, and no RF power is applied. The reactant gas functions as a purge gas. In step 3 which is a surface reaction step, no precursor is supplied, the reactant gas is continuously supplied, and RF power is applied. In step 4 which is a purge step, no precursor is supplied, the reactant gas is continuously supplied, and no RF power is applied. The reactant gas functions as a purge gas. In some embodiments, in step 1, two or more precursors can be supplied in separate pulses or in the same pulse. In some embodiments, a separate purge gas can be used for purging, and vacuum can also be used for purging, wherein the reactant gas may be supplied only in step 3. Steps 2 and 4 can be conducted in any manner as long as the non-adsorbed precursor in step 2 and the non-reacted product in step 4 are removed from the surface. When two or more reactant gases are used, they may be supplied in different pulses, where neither reactant gas is continuously supplied, where RF power is applied in each step. For example, the first reactant gas is He and the second reactant gas is NH₃, thereby first forming SiC and then nitrizing SiC to form SiCN. Alternatively, the first reactant gas is NH₃ and the second reactant gas is He, thereby first forming SiN and then carbonizing SiN to form SiCN.

In some embodiments, the precursor is supplied using a carrier gas, wherein the precursor is vaporized in a tank under an equilibrium vaporization pressure, and the vaporized precursor is supplied with a carrier gas to a reactor, wherein the flow of the precursor is controlled by the inflow gas pressure (the pressure of gas flowing into the reactor). Since ALD is a self-limiting adsorption reaction process, the amount of deposited precursor molecules is determined by the number of reactive surface sites and is independent of the precursor exposure after saturation, and a supply of the precursor is such that the reactive surface sites are saturated thereby per cycle.

In some embodiments, the precursor is supplied together with a secondary precursor, such as hydrocarbon for films having Si—C bonds, in the same pulses.

In PE-ALD, in some embodiments, the following conditions may be employed:

Substrate temperature: 0 to 650° C. (preferably about 100 to about 500° C.)

Precursor pressure: 50 to 1333 Pa (preferably about 100 to about 500 Pa)

Carrier gas (e.g., Ar or He) flow: 500 to 4,000 sccm (preferably about 1,000 to about 2,500 sccm)

Precursor pulse: 0.1 to 10 seconds (preferably about 0.3 to about 3 seconds)

Purge upon the precursor pulse: 0.1 to 10 seconds (preferably about 0.3 to about 3 seconds)

Optional purge gas flow: 100 to 2,000 sccm (preferably about 300 to 1,500 sccm)

RF frequency: 13.56 to 60 MHz

RF power: 10 to 1,500 W (preferably about 100 to about 800 W for a 300-mm wafer)

RF power pulse: 0.1 to 20 seconds (preferably about 0.5 to 10 seconds)

Reactant gas (rare gas) flow: 500 to 4,000 sccm (preferably, He flow at about 1,000 to 2,000 sccm)

Reactant gas (secondary gas) flow: 0 to 1,000 sccm (less than rare gas flow; preferably H₂ flow at about 50 to 500 sccm)

Reactant gas flow (for SiCN): 400 to 3,000 sccm (preferably N2 flow at about 500 to 1,500 sccm)

Purge upon the RF power pulse: 0.1 to 10 seconds (preferably about 0.3 to about 3 seconds)

Optional purge gas flow: 100 to 2,000 sccm (preferably about 300 to 1,500 sccm)

Duration of one cycle: 1 to 30 seconds

Number of cycles repeated: 300 to 1,000

Thickness of film: 5 to 30 nm

Film can also be formed by thermal ALD or radical-enhanced ALD instead of plasma ALD, but plasma ALD is preferred in terms of productivity because thermal ALD requires a longer time for replacement reaction. Also, thermal reaction exhibits marked dependence on temperature and implementing it at low temperatures is difficult. Note that plasma ALD and thermal ALD are interchangeable in an embodiment despite their differences in productivity, etc.

In some embodiments, the ALD is thermal ALD or radical-enhance ALD. steps (i) and (ii) comprise:

(a) supplying the precursor and a dilution gas to a reaction space where the substrate is placed, without supplying the reactant gas, thereby adsorbing the precursor on the surface of the substrate;

(b) continuously supplying the dilution gas while discontinuing the supply of the precursor, without supplying the reactant gas, thereby purging the surface of the substrate;

(c) supplying the reactant gas in an excited state to the reaction space while continuously supplying the dilution gas without the supply of the precursor, thereby reacting the adsorbed precursor and the reactant gas on the surface; and

(d) continuously supplying the dilution gas while discontinuing the supply of the precursor and the reactant gas, thereby purging the surface of the substrate,

where steps (a) to (d) constitute one cycle of the thermal ALD.

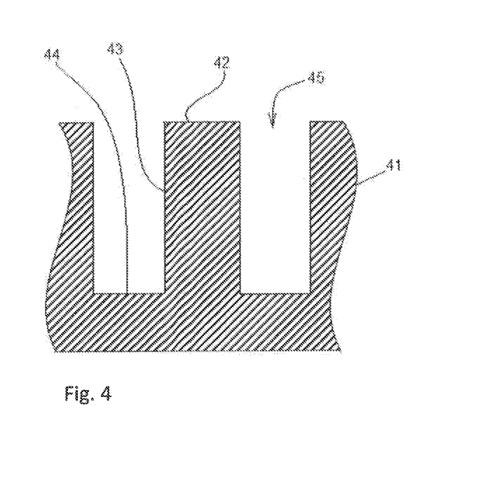

FIG. 3 shows process steps of a thermal ALD or radical-enhanced ALD method for depositing a dielectric film according to another embodiment of the present invention. In FIG. 3, the thermal ALD or radical-enhanced ALD method repeats a cycle which is constituted by steps 1 to 4. In step 1 which is a precursor adsorption step, a precursor is supplied in a pulse, a dilution gas is supplied, and no reactant gas is supplied. In step 2 which is a purge step, no precursor is supplied, the dilution gas is continuously supplied, and no reactant gas is supplied. The dilution gas functions as a purge gas. In step 3 which is a surface reaction step, no precursor is supplied, the dilution gas is continuously supplied, and a reactant gas is supplied, which reactant gas is excited thermally or in a radical form generated in a remote plasma unit. In step 4 which is a purge step, no precursor is supplied, the dilution gas is continuously supplied, and no reactant gas is supplied. The dilution gas functions as a purge gas. In some embodiments, in step 1, two or more precursors can be supplied in separate pulses or in the same pulse. Steps 2 and 4 can be conducted in any manner as long as non-adsorbed precursor in step 2 and non-reacted product in step 4 are removed from the surface. When two or more reactant gases are used, they may be supplied in different pulses, where neither reactant gas is continuously supplied. For example, the first reactant gas is He and the second reactant gas is NH₃, thereby first forming SiC and then nitrizing SiC to form SiCN. Alternatively, the first reactant gas is NH₃ and the second reactant gas is He, thereby first forming SiN and then carbonizing SiN to form SiCN.

The sequence illustrated in FIG. 3 is similar to that illustrated in FIG. 2, except that in FIG. 2, the reactant gas is continuously supplied throughout steps 1 to 4 and RF power is applied only in step 3, whereas in FIG. 3, the dilution gas is continuously supplied throughout steps 1 to 4 and the reactant gas is supplied only in step 3. The conditions for the sequence of FIG. 3 are similar to those for the sequence of FIG. 2. Additional conditions for thermal ALD are as follows:

Substrate temperature: 100° C. to 650° C. (preferably about 300 to about 550° C.)

For radical-enhanced ALD, reactant gas radicals supplied from a remote plasma unit are introduced to the reactor in place of the reactant gas.

In some embodiments, the semiconductor substrate has patterned recesses on which the dielectric film is formed. In some embodiments, each patterned recess includes a top surface, side wall, and bottom surface. In some embodiments, the dielectric film has a side wall coverage of at least about 75% (preferably about 80% or higher), which is defined as a ratio of thickness of film deposited on the side wall to thickness of film deposited on the top surface, where the recess is a Si-line pattern having an opening of 50 to 100 nm and an aspect ratio of 2 to 4.

In some embodiments, the dielectric film is constituted by SiCNH or SiCH. In some embodiments, SiCNH films may be constituted by 30 to 40 atomic % of Si, 35 to 50 atomic % of N, 5 to 15 atomic % of C, and 15 to 25 atomic % of H, and SiCH films may be constituted by 35 to 45 atomic % of Si, 30 to 45% of C, and 15 to 30 atomic % of H.

In some embodiments, any of the disclosed embodiments further comprises, prior to step (i), treating the surface of the substrate with hydrogen in an excited state, without depositing a film on the surface. In some embodiments, the hydrogen in an excited state is a hydrogen plasma. Also, in the above, in some embodiments, the plasma is generated by applying RF power. For example, the pre-treatment can be performed as follows:

Plasma: H₂ plasma

H₂ flow: 10 to 3,000 sccm (preferably about 100 to about 1,000 sccm)

Pressure: 50 to 1,333 Pa (preferably about 100 to about 500 Pa)

Temperature: 100 to 400° C. (preferably about 150 to about 350° C.)

RF power: 10 to 1,500 W (preferably about 100 to about 800 W)

RF frequency: 13.56 MHz to 60 MHz

Duration: 5 to 600 seconds (preferably about 30 seconds to about 2 minutes).

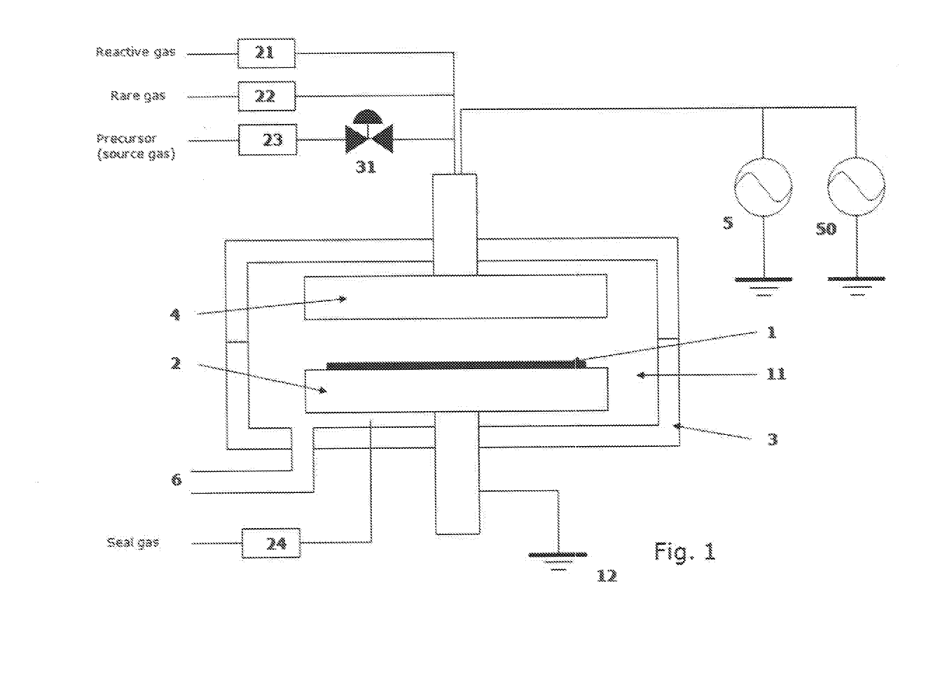

FIG. 1 is a schematic view of a plasma ALD reactor with flow control valves, which can be used in some embodiments of the present invention.

In this example, by providing a pair of electrically conductive flat-plate electrodes 4, 2 in parallel and facing each other in the interior 11 of a reaction chamber 3, applying HRF power (13.56 MHz or 27 MHz) 5 and LRF power of 5 MHz or less (400 kHz˜500 kHz) 50 to one side, and electrically grounding 12 the other side, a plasma is excited between the electrodes. A temperature regulator is provided in a lower stage 2 (the lower electrode), and a temperature of a substrate 1 placed thereon is kept constant at a given temperature. The upper electrode 4 serves as a shower plate as well, and reaction gas and rare gas are introduced into the reaction chamber 3 through a gas flow controller 23, a pulse flow control valve 31, and the shower plate. Additionally, in the reaction chamber 3, an exhaust pipe 6 is provided through which gas in the interior 11 of the reaction chamber 3 is exhausted. Additionally, the reaction chamber is provided with a seal gas flow controller 24 to introduce seal gas into the interior 11 of the reaction chamber 3 (a separation plate for separating a reaction zone and a transfer zone in the interior of the reaction chamber is omitted from this figure). For the pulse flow control valve 31, a pulse supply valve that is used for ALD can suitably be used in some embodiments.

The disclosed embodiments will be explained with reference to specific examples which are not intended to limit the present invention. The numerical numbers applied in the specific examples may be modified by a range of at least ±50% in other conditions, wherein the endpoints of the ranges may be included or excluded. In the present disclosure where conditions and/or structures are not specified, the skilled artisan in the art can readily provide such conditions and/or structures, in view of the present disclosure, as a matter of routine experimentation.

### EXAMPLE

Conventionally, for forming a silicon oxide film by ALD, aminosilane materials are often used, and thus, formation of SiCN and SiC films using an amonosilane precursor was evaluated. As a reactant, H₂, CH₄, N₂, NH₃, and He were used. All of the reactants successfully reacted with the adsorbed aminosilane precursor; however, when film was formed on semiconductor circuits having recesses, the thickness of film deposited on a sidewall was smaller than that of film deposited on a bottom surface or a top surface. This problem is caused by insufficient plasma reaction by reactant species with the adsorbed precursor at the sidewall and bottom surface. For a blanket film formed on a flat horizontal surface, the growth rate per cycle was confirmed to change along a saturation curve in relation to gas supply time and purge time.

In ALD, reactivity between an adsorbed precursor and a reactant is uniquely dependent upon what type of precursor and what type of reactant are used in combination. Certainly, not all of the precursors used for forming silicone oxide films are applicable for forming a highly conformal film. For SiCN or SiC films, since it is not easy to form a Si—C skeleton by providing Si—C bonds from a reactant gas, specific precursors are required for providing Si—C bonds. A precursor having a Si—C—Si bond in its molecule was used in the following examples. As a reactant gas, He, Ar, H₂, and N₂ were evaluated in the examples. Under the conditions used in each example, it was confirmed that the growth rate of blanket films deposited on a flat surface changed along a saturation curve in relation to gas supply time and purge time, i.e., the film formation was conducted by ALD. In the following examples, step coverage was evaluated.

Method and Conditions

A dielectric film was formed on a 300-mm substrate having a patterned surface having an aspect ratio of about 2 and an opening width of about 50 ran under the conditions shown below using the sequence illustrated in FIG. 2 and the PE-ALD apparatus illustrated in FIG. 1. The thickness of film was 30 nm for evaluating film properties.

PE-ALD:

Precursor inflow pressure: 133-1333 Pa (It depended on vapor pressure of precursor)

Substrate temperature: see Table 1

Carrier gas flow: see Table 1

Reactant gas flow (continuous): see Table 1

RF frequency: 13.56 MHz

RF power: see Table 1

Precursor supply time (Step 1): see Table 2

Purge time after precursor pulse (Step 2): see Table 2

RF Plasma exciting time (Step 3): see Table 2

Purge time after RF application (Step 4): see Table 2

Pre-Treatment

Pressure: 50 to 1000 Pa

Substrate temperature: 100 to 400° C.

Treating gas (H₂) flow: 1 SLM

RF frequency: 13.56 MHz

RF power: 500 W

Duration: 1 minute

TABLE 1

| | | | | | | RF | |
|---|---|---|---|---|---|---|---|
| | | Sub. | | Reactant | Carrier | power | Pre- |
| # | Film | (° C.) | Precursor | (SLM) | (SLM) | (W) | treat |
| Com. | SiC | 100 | Hexamethyldisilane | He (1.5) | Ar (1) | 500- | No |
| 1 | | | | | | | |
| Com. | SiC | 400 | Hexamethyldisilane | He (1.5) | Ar (1) | 500- | No |
| 2 | | | | | | | |
| 1 | SiC | 100 | 1,4-Disilabutane | He (1.5) | He (2) | 800- | No |
| 2 | SiC | 200 | 1,4-Disilabutane | He (1.5) | He (2) | 800- | No |
| 3 | SiC | 100 | 1,4-Disilabutane | He (1.5) | He (2) | 500- | No |
| 4 | SiC | 200 | 1,4-Disilabutane | He (1.5) | He (2) | 500- | No |
| 5 | SiC | 400 | 1,4-Disilabutane | He (1.5) | He (2) | 500- | No |
| 6 | SiC | 100 | 1,4,7-Trisilaheptane | He (1.5) | He (2) | 800- | No |
| 7 | SiC | 200 | 1,4,7-Trisilaheptane | He (1.5) | He (2) | 800- | No |
| 8 | SiC | 400 | 1,4,7-Trisilaheptane | He (1.5) | He (2) | 800- | No |
| 9 | SiC | 100 | 1,4,7-Trisilaheptane | He (1.5) | He (2) | 800- | Yes |
| 10 | SiC | 200 | 1,4,7-Trisilaheptane | He (1.5) | He (2) | 800- | Yes |
| 11 | SiC | 100 | 1,4,7-Trisilaheptane | He (1.5) | He (2) | 100- | No |
| | | | | H₂ (0.1) | | | |
| 12 | SiC | 100 | 1,4,7-Trisilaheptane | He (1.5) | He (2) | 100- | Yes |
| | | | | H₂ (0.1) | | | |
| 13 | SiC | 200 | 1,4,7-Trisilaheptane | He (1.5) | He (2) | 100- | No |
| | | | | H₂ (0.1) | | | |
| 14 | SiC | 200 | 1,4,7-Trisilaheptane | He (1.5) | He (2) | 100- | Yes |
| | | | | H₂ (0.1) | | | |
| 15 | SiCN | 100 | 1,4,7-Trisilaheptane | He (1.5) | He (2) | 800- | No |
| | | | | N₂ (1) | | | |
| 16 | SiCN | 100 | 1,4,7-Trisilaheptane | He (1.5) | He (2) | 800- | Yes |
| | | | | N₂ (1) | | | |
| 17 | SiCN | 100 | 1,4,7-Trisilaheptane | He (1.5) | He (2) | 100- | No |
| | | | | N₂ (1) | | | |
| | | | | H₂ (0.1) | | | |
| 18 | SiCN | 100 | 1,4,7-Trisilaheptane | He (1.5) | He (2) | 100- | Yes |
| | | | | N₂ (1) | | | |
| | | | | H₂ (0.1) | | | |

The films obtained above were examined, and the results are shown in Table 2.

TABLE 2

| | ALD cycle | Growth rate | Side/Bottom | Composition |
|---|---|---|---|---|
| # | Steps 1/2/3/4 | (nm/cycle) | coverage (%)* | by FT-IR |
| Com. 1 | 0.5/1/1/0.3 | No film | — | — |
| Com. 2 | 0.5/1/10/0.3 | No film | — | — |
| 1 | 0.1/0.5/1/0.3 | 0.10 | 75/85 | SiCH |
| 2 | 0.1/0.5/1/0.3 | 0.09 | 75/87 | SiCH |
| 3 | 0.1/0.5/10/0.3 | 0.12 | 75/85 | SiCH |
| 4 | 0.1/0.5/10/0.3 | 0.10 | 75/88 | SiCH |
| 5 | 0.1/0.5/10/0.3 | 0.08 | 80/90 | SiCH |
| 6 | 0.1/0.5/10/0.3 | 0.16 | 80/95 | SiCH |
| 7 | 0.1/0.5/10/0.3 | 0.15 | 80/90 | SiCH |
| 8 | 0.1/0.5/10/0.3 | 0.11 | 83/90 | SiCH |
| 9 | 0.1/0.5/10/0.3 | 0.16 | 88/95 | SiCH |
| 10 | 0.1/0.5/10/0.3 | 0.11 | 86/90 | SiCH |
| 11 | 0.1/0.5/1/0.3 | 0.004 | 80/89 | SiCH |
| 12 | 0.1/0.5/1/0.3 | 0.003 | 90/92 | SiCH |
| 13 | 0.1/0.5/1/0.3 | 0.003 | 82/87 | SiCH |
| 14 | 0.1/0.5/1/0.3 | 0.003 | 89/90 | SiCH |
| 15 | 0.1/0.5/10/0.3 | 0.13 | 75/78 | SiCNH |
| 16 | 0.1/0.5/10/0.3 | 0.13 | 80/80 | SiCNH |
| 17 | 0.1/0.5/10/0.3 | 0.01 | 76/80 | SiCNH |
| 18 | 0.1/0.5/10/0.3 | 0.01 | 80/82 | SiCNH |

*% of thickness of sidewall layer and thickness of bottom layer relative to thickness of top layer.

The film type was determined by FT-IR analysis, and the composition analysis results (RBS-HFS method) of films obtained in Examples 6 and 7, for example, are shown below.

TABLE 3

| | Si (atomic %) | C (atomic %) | H (atomic %) |
|---|---|---|---|
| Example 6 | 39 | 41 | 20 |
| Example 7 | 38 | 35 | 27 |

As shown in Table 2, when the precursor has a Si—C—Si bond, the step coverage can be as high as 75% or higher, and even 80% or higher when the substrate temperature is higher (Examples 5 and 8), the number of Si—C—Si bonds is higher (Examples 6-14), the pre-treatment is conducted (Examples 9, 10, 12, 14, 16, and 18). Further, when RF power is higher and/or a plasma pulse is longer, the step coverage becomes higher. However, although Examples 1 and 2 used higher RF power than did Examples 3 and 4, since Examples 1 and 2 used shorter plasma pulses than did Examples 3 and 4, the step coverage of each resultant film was substantially similar.

When H₂ is added to He as a reactant gas, surface reactivity can be increased, thereby lowering RF power (Examples 11-14 and 17 and 18) and shortening plasma duration (Examples 11-14). When H₂ is added to rare gas, ALD can be performed at a temperature of lower than 300° C., RF power of less than 200 W, plasma duration of less than 2 seconds, for example, and thus, damage to an underlying layer can be inhibited. However, when Ar was added to He and H₂, sputtering effect was increased (data not shown), and thus, it is better to use He/H₂ without Ar as a reactant gas.

It will be understood by those of skill in the art that numerous and various modifications can be made without departing from the spirit of the present invention. Therefore, it should be clearly understood that the forms of the present invention are illustrative only and are not intended to limit the scope of the present invention.

1. (canceled)

2. The method according to claim 21, wherein the reactant gas consists of the rare gas.

3. The method according to claim 21, wherein the reactant gas consists of the rare gas and at least another gas constituted by N, H, and/or C.

4. The method according to claim 3, wherein the other gas is selected from the group consisting of nitrogen, ammonia, hydrogen, hydrocarbon, and nitrogen-hydrocarbon.

5. The method according to claim 4, wherein the other gas is hydrogen and/or nitrogen.

6. The method according to claim 2, wherein the rare gas is at least one rare gas selected from Ar, He, Kr, and Xe.

7. The method according to claim 6, wherein the rare gas is He.

8. The method according to claim 3, wherein the rare gas is at least one rare gas selected from Ar, He, Kr, and Xe.

9. The method according to claim 8, wherein the rare gas is He and the other gas is hydrogen and/or nitrogen.

10. (canceled)

11. The method according to claim 21, wherein the ALD is plasma enhanced ALD.

12. The method according to claim 11, wherein steps (i) and (ii) comprise:
(a) supplying the precursor and the reactant gas to a reaction space where the substrate is placed, without applying RF power, thereby adsorbing the precursor on the surface of the substrate;
(b) continuously supplying the reactant gas while discontinuing the supply of the precursor, without applying RF power, thereby purging the surface of the substrate;
(c) applying RF power to the reaction space while continuously supplying the reactant gas without the supply of the precursor, thereby reacting the adsorbed precursor and the reactant gas on the surface; and
(d) continuously supplying the reactant gas while discontinuing the supply of the precursor, thereby purging the surface of the substrate,
where steps (a) to (d) constitute one cycle of the plasma enhanced ALD.

13. The method according to claim 21, wherein the ALD is thermal ALD or radical-enhance ALD.

14. The method according to claim 13, wherein steps (i) and (ii) comprise:
(a) supplying the precursor and a dilution gas to a reaction space where the substrate is placed, without supplying the reactant gas, thereby adsorbing the precursor on the surface of the substrate;
(b) continuously supplying the dilution gas while discontinuing the supply of the precursor, without supplying the reactant gas, thereby purging the surface of the substrate;
(c) supplying the reactant gas in an excited state to the reaction space while continuously supplying the dilution gas without the supply of the precursor, thereby reacting the adsorbed precursor and the reactant gas on the surface; and
(d) continuously supplying the dilution gas while discontinuing the supply of the precursor and the reactant gas, thereby purging the surface of the substrate,
where steps (a) to (d) constitute one cycle of the thermal ALD.

15. (canceled)

16. (canceled)

17. The method according to claim 3, wherein the dielectric film has a side wall coverage of at least 80%.

18. The method according to claim 21, wherein the dielectric film is constituted by SiCNH or SiCH.

19. The method according to claim 21, further comprising, prior to step (i), treating the surface of the substrate with hydrogen in an excited state.

20. The method according to claim 19, wherein the hydrogen in an excited state is a hydrogen plasma.

21. A method of forming a dielectric film having Si—C bonds on a semiconductor substrate by atomic layer deposition (ALD), which comprises:
(i) adsorbing a precursor on a surface of a substrate, said precursor having a Si—C—Si bond in its molecule;
(ii) reacting the adsorbed precursor and a reactant gas on the surface,
wherein all the gases used in steps (i) and (ii) are oxygen-free and halogen-free, one of which gases is a rare gas; and
(iii) repeating steps (i) and (ii) to form a conformal dielectric film constituted by a silicon carbide on the substrate,
wherein the semiconductor substrate has patterned recesses on which the dielectric film is formed, each patterned recess including a top surface, side wall, and bottom surface, and the dielectric film has a side wall coverage of at least 75% which is defined as a ratio of thickness of film deposited on the side wall to thickness of film deposited on the top surface, and
wherein the precursor consists of one or more compounds selected from the group consisting of: 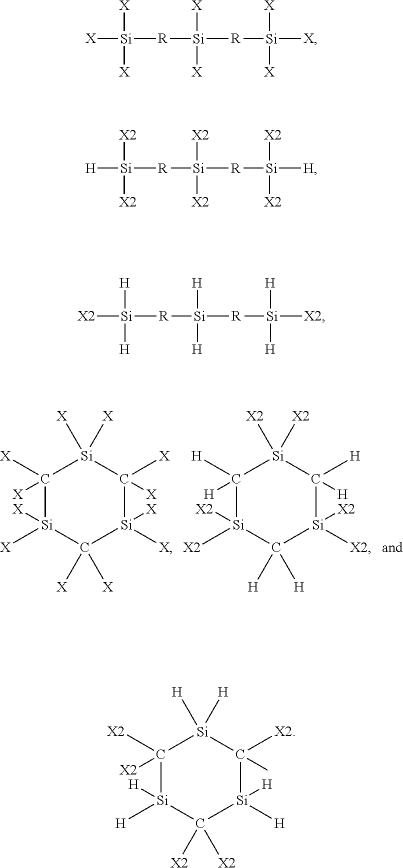
wherein X is H or NₓH_{y}, X2 is CₓH_{y} or NCₓH_{y}, R is CₓH_{y}, NH₂, or NCₓH_{y}, where subscript x and y are integers.

22. A method of forming a dielectric film having Si—C bonds on a semiconductor substrate by atomic layer deposition (ALD), which comprises:
(i) adsorbing a precursor on a surface of a substrate, said precursor having a Si—C—Si bond in its molecule;
(ii) reacting the adsorbed precursor and a reactant gas on the surface,
wherein all the gases used in steps (i) and (ii) are oxygen-free and halogen-free, one of which gases is a rare gas; and
(iii) repeating steps (i) and (ii) to form a conformal dielectric film constituted by a silicon carbide on the substrate,
wherein the semiconductor substrate has patterned recesses on which the dielectric film is formed, each patterned recess including a top surface, side wall, and bottom surface, and the dielectric film has a side wall coverage of at least 75% which is defined,as a ratio of thickness of film deposited on the side wall to thickness of film deposited on the top surface, and
wherein all of the reactant gas reacting with the precursor is constituted by predominantly a rare gas in an excited state.
